(19) United States
(12) Patent Application Publication
(10) Pub. No.: US 2019/0081364 A1
(43) Pub. Date: Mar. 14, 2019

(54) INTEGRATED SENSE BOARD OF ELECTRIC VEHICLE BATTERY MANAGEMENT SYSTEM

(71) Applicant: SF Motors, Inc., Santa Clara, CA (US)

(72) Inventors: Nathalie Capati, Santa Clara, CA (US); Duanyang Wang, Santa Clara, CA (US); Jacob Heth, Santa Clara, CA (US); Binbin Chi, Santa Clara, CA (US)

(21) Appl. No.: 16/118,365

(22) Filed: Aug. 30, 2018

Related U.S. Application Data
(60) Provisional application No. 62/557,677, filed on Sep. 12, 2017.

(51) Int. Cl. H01M 10/42; H05K 1/11; H01M 2/10; H01M 2/20; H01M 2/26; H01M 10/48; B60L 11/18

(52) U.S. Cl. CPC H01M 10/425; B60K 6/28; H01M 2/1077; H01M 2/206; H01M 2/26; H01M 10/486; B60L 11/1877; H05K 2201/10037; H05K 2201/10196; H05K 2201/10189; H05K 2201/10287; H05K 2201/10151; H01M 2220/20; H01M 2010/4271; H05K 1/111

(57) ABSTRACT

Systems, methods, and apparatuses associated with energy storage are provided. A circuit board can include a first contact patch to electrically couple with a first conductive layer of an integrated current collector of a battery block to connect with first polarity terminals of battery cells. The circuit board can include a second contact patch to electrically couple with a second conductive layer of the integrated current collector of the battery block to connect with second polarity terminals of battery cells. The circuit board can include a third contact patch to connect to a thermistor to measure a temperature of the battery block. The circuit board can include embedded conductive traces, and can include a connector to electrically couple the contact patches via the embedded conductive traces to a battery monitoring unit (BMU) to relay a signal indicative of a characteristic of a component of the battery block.

### CROSS-REFERENCES TO RELATED APPLICATIONS

This application claims priority under 35 U.S.C. § 119(e) to U.S. Provisional Application No. 62/557,677, titled “SUBMODULE SENSE BOARD,” filed Sep. 12, 2017, which is hereby incorporated by reference in its entirety.

### BACKGROUND

There is an increasing demand for reliable and higher capacity battery cells for high power, higher performance battery packs, to support applications in plug-in hybrid electrical vehicles (PHEVs), hybrid electrical vehicles (HEVs), or electrical vehicle (EV) systems, for example. Physical, electrical, or other operational characteristics of battery pack modules can indicate whether or not performance of the battery pack module is satisfactory, and can also indicate a need for maintenance or operational adjustments. However, monitoring the performance of these battery packs can be difficult, which can decrease reliability and can hinder maintenance and serviceability in the field.

### SUMMARY

The present disclosure is directed to a battery management system to monitor battery pack modules and their components. A sense circuit board (sometimes referred to as a “sense board” or “circuit board”) can be integrated with a battery block holding battery cells to store and provide electrical energy. The sense circuit board can be directly coupled with various components of the battery block to measure various characteristics of the components. The measurements can be relayed to a battery management unit (BMU) to adjust operations of the battery block.

At least one aspect is directed to an apparatus for storing electrical energy in electric vehicles to power the electric vehicles. The apparatus can include a battery block disposed in a battery block of an electric vehicle to power the electric vehicle. The apparatus can include a plurality of battery cells disposed within the battery block to store electrical energy. The apparatus can include an integrated current collector to electrically couple the plurality of battery cells in parallel. The integrated current collector can have having a first conductive layer to connect with first polarity terminals of the plurality of battery cells and a second conductive layer to connect with second polarity terminals of the plurality of battery cells. The second conductive layer can be electrically isolated from the first conductive layer. The apparatus can include a circuit board to couple with a battery monitoring unit (BMU). The circuit board can be partially incorporated into the battery block. The circuit board can have a first contact patch to electrically couple with the first conductive layer. The circuit board can have a second contact patch to electrically couple with the second conductive layer. The circuit board can have a third contact patch to connect to a thermistor to measure a temperature of the battery block. The circuit board can have a plurality of conductive traces embedded along the circuit board. The circuit board can have a connector to electrically couple the first contact patch, the second contact patch, and the third contact patch via the plurality of conductive traces to the BMU to relay a signal indicative of a characteristic of a component of the battery block.

At least one aspect is directed to a circuit board to measure characteristics of battery cells for powering electric vehicles. The circuit board can include a first contact patch to electrically couple with a first conductive layer of an integrated current collector of a battery block to connect with first polarity terminals of a plurality of battery cells of the battery block. The circuit board can include a second contact patch to electrically couple with a second conductive layer of the integrated current collector of the battery block to connect with second polarity terminals of the plurality of battery cells of the battery block. The second conductive layer can be electrically isolated from the first conductive layer. The circuit board can include a third contact patch to connect to a thermistor to measure a temperature of the battery block. The circuit board can include a plurality of embedded conductive traces. The circuit board can include a connector to electrically couple the first contact patch, the second contact patch, and the third contact patch via the plurality of embedded conductive traces to a battery monitoring unit (BMU) to relay a signal indicative of a characteristic of a component of the battery block.

At least one aspect is directed to a method of storing electrical energy in electric vehicles to power electric vehicles. The method can include providing a circuit board to at least partially incorporate into a battery block. The circuit board can include a first contact patch to electrically couple with a first conductive layer of an integrated current collector of a battery block to connect with first polarity terminals of a plurality of battery cells of the battery block. The circuit board can include a second contact patch to electrically couple with a second conductive layer of the integrated current collector of the battery block to connect with second polarity terminals of the plurality of battery cells of the battery block. The second conductive layer can be electrically isolated from the first conductive layer. The circuit board can include a third contact patch to connect to a thermistor to measure a temperature of the battery block. The circuit board can include a plurality of embedded conductive traces. The circuit board can include a connector to electrically couple the first contact patch, the second contact patch, and the third contact patch via the plurality of embedded conductive traces to a battery monitoring unit (BMU) to relay a signal indicative of a characteristic of a component of the battery block.

### BRIEF DESCRIPTION OF THE DRAWINGS

The accompanying drawings are not necessarily intended to be drawn to scale. Like reference numbers and designations in the various drawings indicate like elements. For purposes of clarity, not every component may be labelled in every drawing. In the drawings:

FIG. 1 depicts an overhead view of an illustrative embodiment of a system for providing energy storage with component monitoring capability;

FIG. 2 depicts an isometric view of an illustrative embodiment of a system for providing energy storage with component monitoring capacity;

FIG. 3 depicts a cross-section view of an illustrative embodiment of a system for providing energy storage with component monitoring capacity.

FIG. 4 depicts an overhead view of an illustrative embodiment of a sense circuit board for a system for providing energy storage with component monitoring capacity;

FIG. 5 depicts a block diagram depicting a cross-sectional view of an illustrative embodiment of an electric vehicle installed with a battery block;

FIG. 6 is an flow diagram of an illustrative embodiment of a method of managing an energy storage device;

FIG. 7 is an flow diagram of an illustrative embodiment of a method of providing energy storage with component monitoring capability; and

FIG. 8 is a block diagram depicting an architecture for a computer system that can be employed to implement elements of the systems and methods described and illustrated herein.

### DETAILED DESCRIPTION

Following below are more detailed descriptions of various concepts related to, and implementations of, methods, apparatuses, devices, and systems of a battery management system to monitor battery block modules and their components. The various concepts introduced above and discussed in greater detail below may be implemented in any of numerous ways.

Described herein are methods, devices, and apparatuses for battery blocks with at least one integrated circuit board to provide a connection with a component of a battery block (e.g., a component of a battery block within a battery pack) to relay data related to characteristics of the component to a battery monitoring unit. The battery blocks with the integrated circuit board can be for an automotive configuration. An automotive configuration includes a configuration, arrangement or network of electrical, electronic, mechanical or electromechanical devices within a vehicle of any type. An automotive configuration can include battery cells for battery blocks in electric vehicles (EVs). EVs can include electric automobiles, cars, motorcycles, scooters, passenger vehicles, passenger or commercial trucks, and other vehicles such as sea or air transport vehicles, planes, helicopters, submarines, boats, or drones. EVs can be fully autonomous, partially autonomous, or unmanned. EVs can include various components that run on electrical power. These various components can include an electric engine, an entertainment system (e.g., a radio, display screen, and sound system), on-board diagnostics system, and electric control units (ECUs) (e.g., an engine control module, a transmission control module, a brake control module, and a body control module), among other components.

Battery blocks can include or be connected with a battery management unit (BMU) to measure various characteristics of components in the battery block, such as individual battery cells, submodules with groups of battery cells, and cold plates thermally coupled to the battery cells. The measured characteristics can include a temperature from the released heat and a voltage and current outputted from the battery cells. Based on the measurements, the BMU can perform power control and temperature control by dynamically changing operations of the battery block to achieve performance criteria. For example, when the voltage and current outputted from the battery cells is outside the specifications or tolerance levels of the performance criteria, the BMU can increase or decrease the voltage and current drawn from at least a portion of the battery cells. In addition, when the temperature of the submodules is greater than the tolerance level designated by the performance criteria, the BMU can increase an amount of coolant provided to the affected submodules to regulate heat. Achieving the performance criteria can involve obtaining accurate and precise measurements of the characteristics of the components in the battery block.

One approach in obtaining measurements of these characteristics can entail directly connecting sense lines onto a source of the measurements, such as the components of the battery block. The sense line can be comprised of an electrically conductive material to measure voltage or temperature or to measure temperature. The sense line can be extended from the BMU and can be attached to the components to be measured by soldering one end of along an outer surface of the component. Attaching sense lines in this manner, however, can be problematic for a number of reasons. For one, it may be difficult to directly attach sense lines onto the outer surface of the components to be measured for accurate and precise measurements. For example, there may be a limited amount of space for sprouting sense lines, dependent on the number of sense lines to be attached per submodule and an amount of space available on the outer surface of the components to be measured. This difficulty may be exacerbated in densely packed battery blocks with constrained spacing between battery cells and size of the submodules holding the battery cells. Non-direct attachment of sense lines to the components may result in inaccurate, imprecise, and unreliable measurements of the characteristics of the components. For another, manually soldering or wire bonding senses line onto the outer surface of the component may yield inconsistent bond quality. Inconsistent bonding can result in unreliable and inaccurate measurements of the characteristics of the battery block. Moreover, poor bonding can lead to subsequent detachment of the sense lines, leading to no measurements acquired through the affected sense lines. Not to mention, manual soldering or wire bonding of sense lines may substantially increase the assembly time of the battery blocks in connecting with the BMUs relative to assembly without soldering or wire bonding.

To address the technical problems arising from soldering or wire bonding sense lines with the various components of the battery pack, a sense circuit board can be integrated onto the battery pack (e.g., integrated with one or more a battery blocks) to directly connect with the components to be measured. The sense circuit board (sometimes referred herein as a “senseboard”, “circuit board” or “sense board”) can be incorporated onto a surface of the battery pack (e.g., surface of a battery block), and can function as a localized node or a point-to-point connection between the measured components and the BMU. The sense circuit board can have one or more contact patches to directly connect with the component measured, without any soldering. One of the contact patches can be directly connected with a positive terminal of a submodule for the battery cells contained therein. Another contact patch can be directly connected with a negative terminal of the submodule. Another contact patch can be directly connected with a thermistor of the submodule. These contact patches can be connected via a set of embedded trace lines along a surface of the sense circuit board to a set of connector pins to be attached to a data harness of the BMU. The connections with the first two contact patches can be used by the BMU to measure the voltage and current outputted or generated by the battery cells of the submodule. The connection with the third contact patch can be used by the BMU to measure a temperature of the heat released or generated from the submodule. As the contact patches are directly connected with the components to be measured, the accuracy, precision, and the reliability of the measurements can be improved, as compared with a BMU located away from various components of the battery block. Additionally, the likelihood that the BMU is to be disconnected from the measured components can be reduced.

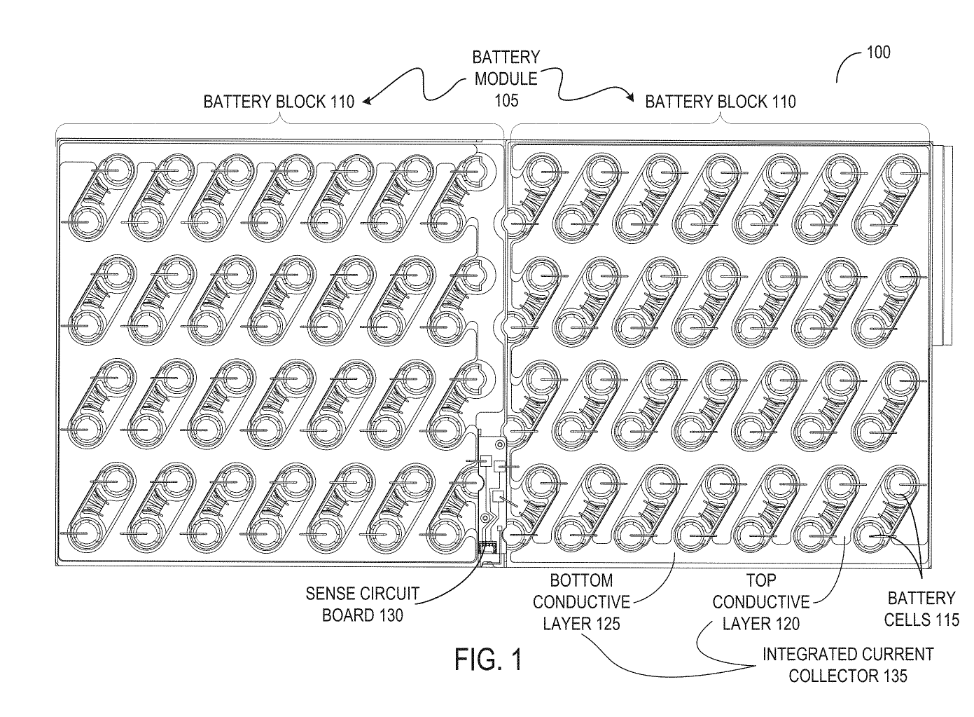

FIG. 1, among others, depicts an overhead view of a system or apparatus 100 for providing energy storage with component monitoring capability. The apparatus 100 can include a set of battery cells 115 to store and to provide electrical energy. The battery cells 115 can include a lithium-air battery cell, a lithium ion battery cell, a nickel-zinc battery cell, a zinc-bromine battery cell, a zinc-cerium battery cell, a sodium-sulfur battery cell, a molten salt battery cell, a nickel-cadmium battery cell, or a nickel-metal hydride battery cell, among others. The battery cell 115 can have or define a positive terminal and a negative terminal. Both the positive terminal and the negative terminal can be accessed or defined along one surface of the battery cell 115 (e.g., as depicted). For example, the positive terminal can be defined on a central portion of the top surface of the battery cell 115, while the negative terminal can be defined on a side wall extending up and around the central portion of the top surface of the battery cell 115. The surface of the battery cell 115 defining the positive and the negative terminal can be exposed (e.g., to air). A shape of the battery cell 115 can be a prismatic casing with a polygonal base, such as a triangle, square, a rectangular, a pentagon, or a hexagon. The shape of the battery cell 115 can also be cylindrical casing or cylindrical cell with a circular (e.g., as depicted), ovular, or elliptical base, among others. A height of each battery cell 115 can be 60 mm to 100 mm. A width or diameter of each battery cell 115 can be 16 mm to 30 mm. A length of each battery cell 115 can be 16 mm to 30 mm. Each battery cell 115 can have an output of 2V to 4V.

The apparatus 100 can include at least one battery block 110 (sometimes referred herein as a “battery block”). A set of battery cells 115 can form a battery block 110. The battery block 110 can support or include at least one battery cell 115. Each battery block 110 can define or include one or more holders. Each holder can be a volume of space extending partially from one side of the battery block 110. Each holder can contain, support, or house at least one of the battery cells 115. The battery block 110 can be comprised of electrically insulating, but thermally conductive material around the holder for the battery cells 115. Examples of thermally conductive material for the battery block 110 can include a ceramic material (e.g., silicon nitride, silicon carbide, titanium carbide, zirconium dioxide, and beryllium oxide) and a thermoplastic material (e.g., acrylic glass, polyethylene, polypropylene, polystyrene, or polyvinyl chloride), among others. A shape of the battery block 110 can be a prismatic casing with a polygonal base, such as a triangle, a square, a rectangular (e.g., as depicted), a pentagon, or a hexagon, among others. The shape of the battery block 110 can also be cylindrical casing or cylindrical cell with a circular, ovular, or elliptical base, among others. The shapes of the battery blocks 110 can vary from one another. A height of each battery block 110 can be 65 m to 100 mm. A width or diameter of each battery block 110 can be 150 mm to 170 mm. A length of each battery block 110 can be 150 mm to 170 mm. The voltage outputted by the battery cells 115 of the battery block 110 can range 2V to 450V.

The battery block 110 can have at least one top conductive layer 120 and at least one bottom conductive layer 125. The top conductive layer 120 and the bottom conductive layer 125 can together form part of an integrated current collector 135. The electrically conductive material for the top conductive layer 120 and the bottom conductive layer 125 can include a metallic material, such as aluminum, an aluminum alloy with copper, silicon, tin, magnesium, manganese or zinc (e.g., of the aluminum 1000, 4000, or 5000 series), iron, an iron-carbon alloy (e.g., steel), silver, nickel, copper, and a copper alloy, among others. Both the top conductive layer 120 and the bottom conductive layer 125 can be along one or more surfaces of the battery block 110 (e.g., along a top side as depicted). The top conductive layer 120 and the bottom conductive layer 125 can at least partially span across the one or more surfaces of the battery block 110. For example, both the top conductive layer 120 and the bottom conductive layer 125 can at least partially span the top surface of the battery block 110 as depicted. The top conductive layer 120 and the bottom conductive layer 125 can be parallel or substantially parallel to each other (e.g., deviation of 0° to) 15°. A shape of the top conductive layer 120 and the bottom conductive layer 125 can be a prismatic casing with a polygonal base, such as a triangle, a square, a rectangular (e.g., as depicted), a pentagon, or a hexagon, among others. An overall shape of the top conductive layer 120 and the bottom conductive layer 125 can generally match an overall shape of one surface of the battery block 110, and can be a circular, ovular, or elliptical base, among others. The shapes of the top conductive layer 120 and the bottom conductive layer 125 can vary from one another. A thickness of each of the top conductive layer 120 and the bottom conductive layer 125 can be 0.5 mm to 5 mm. A width or diameter of each of the top conductive layer 120 and the bottom conductive layer 125 can match the width or the diameter of the battery block 110, and can be 150 mm to 170 mm. A length of each of the top conductive layer 120 and the bottom conductive layer 125 can match the width or the diameter of the battery block 110, and can be 150 mm to 170 mm.

The top conductive layer 120 and the bottom conductive layer 125 of the integrated current collector 135 can have or define a set of openings for the holders to house the battery cells 115. The openings defined on the top conductive layer 120 can be aligned with the openings defined on the bottom conductive layer 125, and vice versa. Each opening defined on the top conductive layer 120 and the bottom conductive layer 125 can expose the positive terminal and the negative terminal of the battery cell 115 passing through the opening. At least a portion of the battery cells 115 when arranged or disposed in the battery block 110 can pass through the openings of both the top conductive layer 120 and the bottom conductive layer 125. A shape of each opening defined by the top conductive layer 120 and the bottom conductive layer 125 can generally match the shape of the battery cells 115. A shape of the opening can be a prismatic casing with a polygonal base, such as a triangle, square, a rectangular, a pentagon, or a hexagon. The shape of the openings defined on the top conductive layer 120 and the bottom conductive layer 125 can also be a circular (e.g., as depicted), ovular, or elliptical base, among others. A length of each opening can be 16 mm to 30 mm. A width or diameter of each opening can be 16 mm to 30 mm.

The top conductive layer 120 and the bottom conductive layer 125 can electrically couple to the set of battery cells 115 housed in the battery block 110 in parallel. The top conductive layer 120 and the bottom conductive layer 125 can define or can correspond to a positive terminal and a negative terminal for the battery block 110. The positive terminal for the battery block 110 can correspond to or can be electrically coupled with the positive terminals of the set of battery cells 115 in the battery block 110. The negative terminal for the battery block 110 can correspond to or can be electrically coupled with the negative terminals of the set of battery cells 115 in the battery block 110. Both the positive terminal and the negative terminal of the battery block 110 can be defined along one surface of the battery block 110 (e.g., along the top surface as depicted). The top conductive layer 120 and the bottom conductive layer 125 can correspond to opposite polarities of the battery block 110. For example, the top conductive layer 120 can correspond to the positive terminal of the battery block 110, and can be electrically coupled with the positive terminal of each battery cell 115 in the battery block 110. On the other hand, the bottom conductive layer 125 can correspond to the negative terminal of the battery block 110, and can be electrically coupled with the negative terminal of each battery cell 115 in the battery block 110. Conversely, the top conductive layer 120 can correspond to the negative terminal of the battery block 110, and can be electrically coupled with the negative terminal of each battery cell 115 in the battery block 110. On the other hand, the bottom conductive layer 125 can correspond to the positive terminal of the battery block 110, and can be electrically coupled with the positive terminal of each battery cell 115 in the battery block 110. The battery block 110 can have or define an electrical ground for the battery cells 115 contained therein. The electrical ground of the battery block 110 can be along one surface of the battery block 110 (e.g., along a bottom surface or a side wall). The surface defining the electrical ground can differ from the side defining the positive terminal and the negative terminal for the battery block 110. In this manner, electrical power stored in the battery cells 115 can transverse along the top conductive layer 120 and the bottom conductive layer 125. Thus, voltage and current can be provided through the top conductive layer 120 and the bottom conductive layer 125 of the integrated current collector 135.

The system can include at least one battery module 105. A set of battery blocks 110 can form the battery module 105. The battery module 105 can include at least one of the battery blocks 110. Each battery block 110 of the battery module 105 can be disposed or arranged next to one another. The arrangement of the battery blocks 110 in the battery module 105 can be in parallel (e.g., as depicted) or in series, or any combination thereof. The battery module 105 can have or define a positive terminal and a negative terminal. The positive terminal for the battery module 105 can correspond to or can be electrically coupled with the positive terminals of the set of battery cells 115 in the battery module 105 across the battery blocks 110. The negative terminal for the battery block 110 can correspond to or can be electrically coupled with the negative terminals of the set of battery cells 115 in the battery module 105 across the battery blocks 110. Both the positive terminal and the negative terminal of the battery module 105 can be defined along a top surface of the battery block 110. The top surface of the battery module 105 can be exposed (e.g., to air). An overall shape of the battery module 105 can depend on the arrangement and the individual shapes of the battery blocks 110. The dimensions of the battery module 105 can be a multiple of the dimensions of the battery blocks 110 (e.g., 8×1). A height of the battery module 105 can be 65 m to 100 mm. A width or diameter of the battery module 105 can be 100 mm to 330 mm. A length of the battery module 105 can be 160 mm to 1400 mm. For example, when the battery module 105 includes two battery blocks 110, the length can be 160 mm and the width can be 700 mm. When the battery module 105 includes eight battery blocks 110 in series, the length can be 1400 mm and the width can be 330 mm.

The apparatus 100 can include at least one battery pack. The battery pack can include a set of battery modules 105. Each battery module 105 of the battery pack can be arranged or disposed adjacent to one another. The arrangement of the battery modules 105 in the battery pack can be in parallel or in series, or any combination thereof. To form the battery pack, the battery blocks 110 can be fastened, attached, or otherwise joined to one another. For example, a side wall of the battery blocks 110 can include interlocking joints to attach one battery block 110 to another battery module 105 to form the battery pack. In addition, the set of battery blocks 110 can be attached to one another using a fastener element, such as a screw, a bolt, a clasp, a bucket, a tie, or a clip, among others. The battery pack can have or define a positive terminal and a negative terminal. The positive terminal for the battery pack can correspond to or can be electrically coupled with the positive terminals of the set of battery cells 115 in the battery pack across the battery modules 105. The negative terminal for the battery module 105 can correspond to or can be electrically coupled with the negative terminals of the set of battery cells 115 in the battery pack across the battery modules 105. Both the positive terminal and the negative terminal of the battery pack can be defined or located along a top surface of the battery module 105. An overall shape of the battery pack can depend on the arrangement and the individual shapes of the battery blocks 110 and battery modules 105. A height of the battery pack can be 120 mm to 160 mm. A width or diameter of the battery pack can be 1400 mm to 1700 mm. A length of the battery pack can be 2100 mm to 2600 mm.

The apparatus 100 can include at least one sense circuit board 130 (referred herein sometimes as a “sense board” or “circuit board”). The sense circuit board 130 can be at least partially incorporated or integrated into at least one of the battery blocks 110 of the battery module 105. At least a portion of the sense circuit board 130 can be situated, disposed, or arranged along one surface of the battery block 110 of the battery module 105 (e.g., along the top surface as depicted). When disposed, at least one side of the sense circuit board 130 can be flush with the surface of the battery block 110. The sense circuit board 130 can be coplanar, parallel, or on a substantially parallel plane (e.g., with deviation of between 0° to 15°) as the top conductive layer 120 and the bottom conductive layer 125 of the integrated current collector 135. A single sense circuit board 130 can be incorporated into multiple battery blocks 110. A portion of the sense circuit board 130 can be incorporated or integrated with a first battery block 110 and another portion of the sense circuit board 130 can be incorporated or integrated with a second battery block 110. An overall shape of the sense circuit board 130 can be a circular, ovular, or elliptical base, among others. A thickness of the sense circuit board 130 can be 0.75 mm to 2 mm. A width or diameter of the sense circuit board 130 can be 40 mm to 60 m. A length of the sense circuit board 130 can be 300 mm to 400 mm. The sense circuit board 130 can be a printed circuit board with one or more electrically conductive vias along or through an electrically insulating substrate. An electrically conductive via can be comprised of copper, aluminum, nickel, tin, lead, or gold, among others (e.g., formed on a sidewall of the via or filling a volume of the via). The electrically conductive via can be electrically coupled with various components of the battery module 105, such as the top conductive layer 120, the bottom conductive layer 125, the battery block 110, or any of the battery cells 115. The electrically insulating substrate can be comprised of a dielectric composite material, such as a synthetic resin bonded paper (e.g., FR-1, fr-2, FR-4, CEM-1, CEM-4, Teflon, and RF-35). The substrate can be an insulated metal substrate with the conductive vias defined therein.

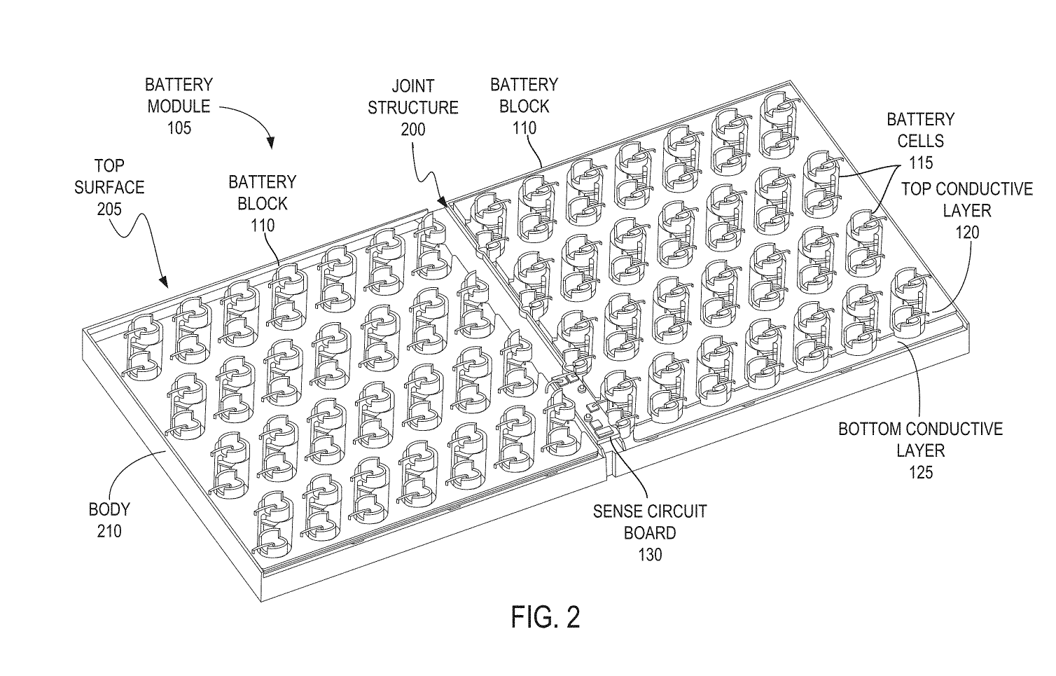

FIG. 2, among others, depicts an isometric view of the apparatus 100 for providing energy storage with component monitoring capacity (e.g., ability or capability). As illustrated, the battery module 105 can define or have at least one joint structure 200. The joint structure 200 can be defined along between multiple battery blocks 110 of the battery module 105 (e.g., two battery blocks 110 as shown). The joint structure 200 can interlock, fasten, attach, or otherwise join one battery block 110 with another battery block 110. To form the battery module 105, the battery blocks 110 can be fastened, attached, or otherwise joined to one another via the joint structure 200. For example, a side wall of the battery blocks 110 can include interlocking joints to attached one battery block 110 to another battery block 110 to form the battery module 105. In addition, the set of battery blocks 110 can be attached to one another using a fastener element, such as a screw, a bolt, a clasp, a bucket, a tie, or a clip, among others. The joint structure 200 can extend one side of at least one battery block 110 joined with another side of at least one other battery block 110. At least a portion of the sense circuit board 130 can be situated, arranged, or otherwise disposed on the joint structure 200. A portion of a surface of the sense circuit board 130 can be flush with one surface (e.g., a top surface) of the joint structure 200. The sense circuit board 130 can be integrated with two or more battery blocks 110 by extension over the joint structure 200. For example, the sense circuit board 130 can be integrated between two of the battery blocks 110 over the joint structure 200 as depicted. The sense circuit board 130 can be also integrated generally in the middle of four battery blocks 110 over the joint structure 200, at least partially spanning the top surfaces of the four battery blocks 110.

The battery module 105 can define or have at least one top surface 205 and at least one body 210. The body 210 can correspond to a portion of the battery module 105 below the bottom conductive layer 125 of the integrated current collector 135. The top surface 205 can correspond to the same side of the battery module 105 defining the positive terminal and the negative terminal of the battery blocks 110. The top surface 205 can be coplanar between multiple battery blocks 110 of the battery module 105 (e.g., as depicted). The top surface 205 can be in different substantially parallel planes (e.g., deviation within 0° to 15°) between the multiple battery blocks 110 of the battery module 105. The top surface 205 can correspond to the side of the battery pack 105 from which the battery block 110 and the battery cells 115 can extend. The body 210 of the battery module 105 can contain, support, house, or otherwise include a bottom portion of the battery block 110 below the top surface 205. Additionally, the body 210 of the battery module 105 can contain, support, house, or otherwise include a bottom portion of the battery cells 115 below the top surface 205. The body 210 can be comprised of an electrically insulating and thermally conductive material. The material for the body 210 of the battery module 105 can include a ceramic material (e.g., silicon nitride, silicon carbide, titanium carbide, zirconium dioxide, and beryllium oxide) and a thermoplastic material (e.g., acrylic glass, polyethylene, polypropylene, polystyrene, or polyvinyl chloride), among others. A top portion of the battery cells 115 of the battery blocks 110 can extend from the body 210 of the battery pack above the top surface 205. In addition, a top portion of the battery block 110 can extend from the body 210 of the battery module 105 above the top surface 205. At least a portion of the joint structure 200 can lie above the top surface 205.

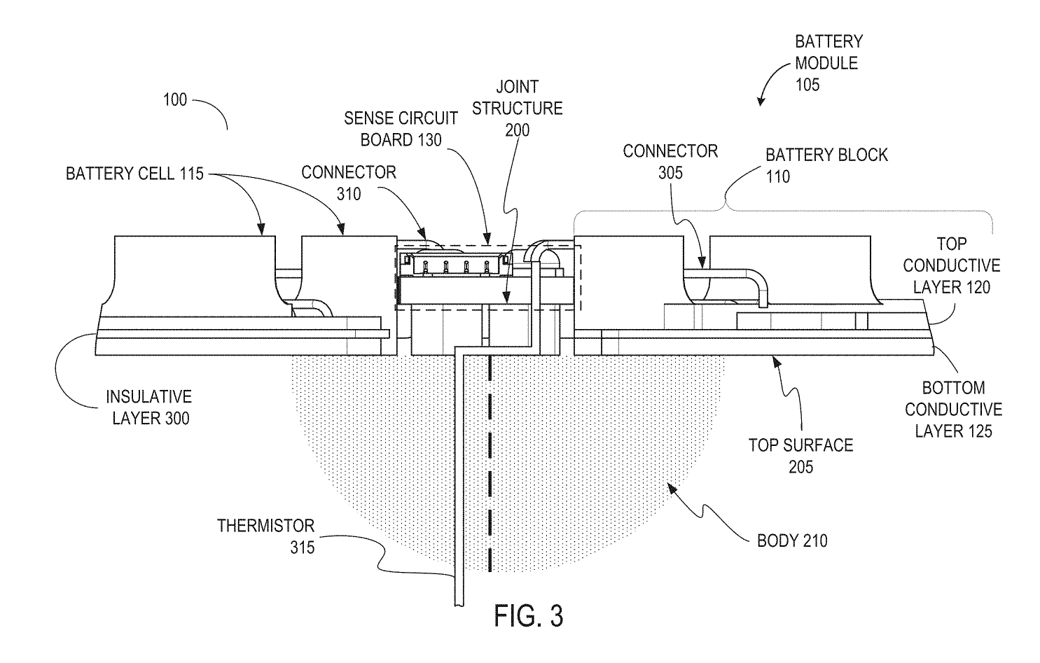

FIG. 3, among others, depicts a cross-section view of an example embodiment of an apparatus 100 for providing energy storage with component monitoring capacity. As illustrated, each battery block 110 can include at least one insulating layer 300. One insulating layer 300 can electrically isolate the top conductive layer 120 and the bottom conductive layer 125. The top conductive layer 120 and the bottom conductive layer 125 can be physically separated from each other via the insulating layer 300. Another insulating layer 300 can electrically isolate the top conductive layer 120 from any portion of the battery cell 115 corresponding to the polarity terminal opposite of the top conductive layer 120. Another insulating layer 300 can electrically isolate the bottom conductive layer 125 from any portion of the battery cell 115 corresponding to the polarity terminal opposite of the bottom conductive layer 125. For example, if the top conductive layer 120 corresponds to the positive terminal of the battery block 110, the insulating layer 300 can electrically isolate the top conductive layer 120 from the negative terminal of the battery cells 115. In addition, the insulating layer 300 can electrically isolate the bottom conductive layer 125 corresponding to the positive terminal from the positive terminal of the battery cells 115. The insulating layer 300 can be or include an electrically insulating material. The electrically insulating material for the insulating layer 300 can include a ceramic material (e.g., silicon nitride, silicon carbide, titanium carbide, zirconium dioxide, and beryllium oxide) and a thermoplastic material (e.g., acrylic glass, polyethylene, polypropylene, polystyrene, or polyvinyl chloride), among others.

The sense circuit board 130 can be electrically coupled with the top conductive layer 120 via at least one first connector 305. The first connector 305 can be electrically coupled with at least one of the conductive vias (e.g., voltage trace lines) of the sense circuit board 130. The sense circuit board 130 can be electrically coupled with the bottom conductive layer 125 via at least one second connector 310. The second connector 310 can be electrically coupled with at least one of the conductive vias (e.g., voltage trace lines) of the sense circuit board 130. The first connector 305 and the second connector 310 each can be comprised of an electrically conductive material. The electrically conductive material for the first connector 305 and the second connector 310 can include a metallic material, such as aluminum, an aluminum alloy with copper, silicon, tin, magnesium, manganese or zinc (e.g., of the aluminum 1000, 4000, or 5000 series), iron, an iron-carbon alloy (e.g., steel), silver, nickel, copper, and a copper alloy, among others. In this manner, measurements of voltage and current from the battery cells 115 via the top conductive layer 120 and the bottom conductive layer 125 through the first connector 305 and the second connector 310 to the sense circuit board 130.

The sense circuit board 130 can be coupled with at least one sensor to measure (e.g., detect, or receive information about) one or more characteristics of the components of the battery module 105. The sensor can be in direct contact with an outer surface of the component of the battery module 105 to be measured, such as the top conductive layer 120, the bottom conductive layer 125, the battery block 110, the individual battery cells 115, and the insulating layer 300 among others. The sensor can be situated, arranged, or disposed within the battery module 105. For example, the sensor can be placed within the body 210 of the battery module 105 generally between two battery blocks 110 as illustrated in FIG. 3. The sensor can be arranged or disposed within the battery block 110, such as within the holders for supporting the battery cells 115. The sensor can be arranged or disposed along a surface of the battery module 105 or one the components therein, such as along the top surface 205 of the battery module 105, top surface of the battery block 110, a side wall of the battery block 110, and a bottom surface of the battery module 105. Arranged along one of the surface of one of the battery block 110, the sensor can be situated between multiple battery blocks 110 to measure the characteristics of the adjacent battery blocks 110. The sensor can convey measurements or signals to the sense circuit board 130 via the coupling with the sense circuit board 130.

The sensor coupled with the sense circuit board 130 can include a thermometer to measure a temperature of the battery module 105. The thermometer can be a thermistor 315 as depicted. Other example of thermometers can include an infrared thermometer, a liquid crystal thermometer, a vapor pressure thermometer, a column block thermometer, and a thermocouple, a quartz thermometer, among others. The sensor coupled with the sense circuit board 130 can include at least one pressure gauge or a force meter to measure pressure exerted from within the battery blocks 110. The force meter can be a dynamometer, a newton meter, and a spring scale, among others to measure force exerted against an outer surface of the battery cell 115 or the battery block 110. The pressure gauge can include a hydrostatic pressure gauge (e.g., a piston gauge, a liquid column, and a McLeod gauge), a mechanical gauge (e.g., a bellow, a Bourdon gauge, and a diaphragm), an electronic pressure sensor (e.g., a capacitive sensor, an electromagnetic gauge, a piezoresistive strain gauge, and an optical sensor), and a thermal conductivity gauge (e.g., Pirani gauge), among others. The sensor coupled with the sense circuit board 130 can include a gas detector to identify one or more gaseous substances released from the battery block 110 or from the individual battery cells 115 in the battery block 110. The gas detector can also determine a concentration (measured in parts-per notation) of the one or more gaseous substances released from the battery block 110. The gaseous substances identified by the gas detector can include hydrocarbons, ammonia, carbides (e.g., carbon monoxide and carbon dioxide), cyanide, halide, sulfides (e.g., hydrogen sulfide, sulfur dioxide, sulfur trioxide, and disulfur monoxide), nitrides, fluorides (e.g., hydrogen fluoride and phosphoryl fluoride), volatile organic compounds (e.g., formaldehyde and benzene), and phosphites among others. The gas detector of the sensor can include an electrochemical gas sensor, a flame ionization detector, an infrared point sensor, a pellistor (e.g., catalytic bead sensor), thermal conductivity meter, and an ultrasonic gas leak detector, among others.

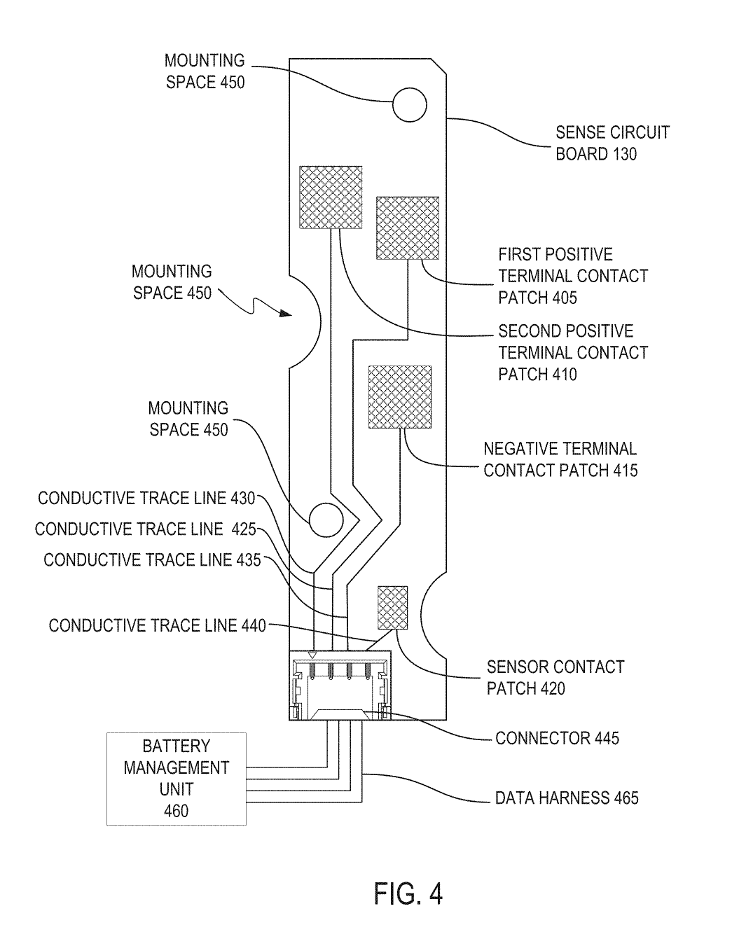

FIG. 4, among others, depicts an overhead view of the sense circuit board 130 for the apparatus 100 for providing energy storage with component monitoring capacity. The sense circuit board 130 can define or have one or more contact patches, such as at least one first positive terminal contact patch 405, at least one second positive terminal contact patch 410, at least one negative terminal contact patch 415, and at least one sensor contact patch 420, among others. Each contact patch of the sense circuit board 130 can define an area of electrically conductive material along the sense circuit board 130 to electrically couple with one or more components of the battery module 105, such as the battery block 110, the top conductive layer 120, the bottom conductive layer 125, the individual battery cells 115, and sensors, among others. The coupling with the various components of the battery module 105 can be direct, without any soldering. Each contact patch can be electrically isolated from one another. The electrically conductive materials for the contact patch can include a metallic material, such as aluminum, an aluminum alloy with copper, silicon, tin, magnesium, manganese or zinc (e.g., of the aluminum 1000, 4000, or 5000 series), iron, an iron-carbon alloy (e.g., steel), silver, nickel, copper, and a copper alloy, among others. The contact patch can be of any shape, such as a triangle, a square, a rectangular (e.g., as depicted), a pentagon, or a hexagon, among others. The shape of the contact patch can also be circular, ovular, or elliptical, among others. The length of the contact patch can range between 1 mm to 4 mm. The width or diameter of the contact patch can range between 1 mm to 4 mm. The shapes and the dimensions can vary among the contact patches of the sense circuit board 130.

The sense circuit board 130 can define or have at least one first positive terminal contact patch 405. The first positive terminal contact patch 405 can be electrically coupled with the positive terminal defined by the battery block 110. The coupling of the first positive terminal contact patch 405 with the positive terminal of the battery block 110 can be in series to measure current drawn from the battery cells 115 of the battery block 110. The coupling of the first positive terminal contact patch 405 with the positive terminal of the battery block 110 can be in parallel to measure voltage drawn from the battery cells 115 of the battery block 110. The positive terminal of the battery block 110 can correspond to or can be coupled with the top conductive layer 120. The first positive terminal contact patch 405 can be coupled with the top conductive layer 120 without any soldering via wire bonding, ball bonding, compliant bonding, or direct contact, among others. The first positive terminal contact patch 405 can be coupled with the top conductive layer 120 via the connector 305 attached to the top conductive layer 120. Conversely, the positive terminal of the battery block 110 can correspond to or can be coupled with the bottom conductive layer 125. first positive terminal contact patch 405 The first positive terminal contact patch 405 can be coupled with the bottom conductive layer 125 without any soldering via wire bonding, ball bonding, compliant bonding, or direct contact, among others. For example, the first positive terminal contact patch 405 can be coupled with the top conductive layer 120 via the connector 305 attached to the top conductive layer 120 of the battery block 110 depicted on the right.

The sense circuit board 130 can define or have at least one second positive terminal contact patch 410. The second positive terminal contact patch 410 can be electrically coupled with the positive terminal defined by another battery block 110 (different from the battery block 110 coupled to the first positive terminal contact patch 405). For example, the first positive terminal contact patch 405 can be electrically coupled with the positive terminal of the battery block 110 on the right side of the sense circuit board, whereas the second positive terminal contact patch 410 can be electrically coupled with the positive terminal of the battery block 110 on the left side (e.g., as depicted in FIG. 1). The coupling of the second positive terminal contact patch 410 with the positive terminal of the battery block 110 can be in series to measure current drawn from the battery cells 115 of the battery block 110. The coupling of the second positive terminal contact patch 410 with the positive terminal of the battery block 110 can be in parallel to measure voltage drawn from the battery cells 115 of the battery block 110. The positive terminal of the battery block 110 can correspond to or can be coupled with the top conductive layer 120 the battery block 110 corresponding to the positive terminal. The second positive terminal contact patch 410 can be coupled with the top conductive layer 120 without any soldering via wire bonding, ball bonding, compliant bonding, or direct contact, among others. The second positive terminal contact patch 410 can be coupled with the top conductive layer 120 via the connector 305 attached to the top conductive layer 120. Conversely, the positive terminal of the battery block 110 can correspond to or can be coupled with the bottom conductive layer 125 corresponding to the positive terminal of the battery block 110. second positive terminal contact patch 410 The second positive terminal contact patch 410 can be coupled with the bottom conductive layer 125 without any soldering via wire bonding, ball bonding, compliant bonding, or direct contact, among others. For example, the second positive terminal contact patch 410 can be coupled with the top conductive layer 120 via the connector 310 attached to the top conductive layer 120 of the battery block 110 depicted on the left.

The sense circuit board 130 can define or have at least one negative terminal contact patch 415 (sometimes referred herein as a ground contact patch). When functioning as the negative terminal patch, the negative terminal contact patch 415 can be electrically coupled with the negative terminal defined by the battery block 110. The coupling of the negative terminal contact patch 415 with the negative terminal of the battery block 110 can be in series to measure current drawn from the battery cells 115 of the battery block 110. The coupling of the negative terminal contact patch 415 with the negative terminal of the battery block 110 can be in parallel to measure voltage drawn from the battery cells 115 of the battery block 110 relative to the voltage measurement at the positive terminals of any one or more of the battery blocks 110. The negative terminal contact patch 415 can be electrically coupled with conductive layer (e.g., top conductive layer 120 and bottom conductive layer 125) opposite of the conductive layer coupled with the first positive terminal contact patch 405. The negative terminal of the battery block 110 can correspond to or can be coupled with the top conductive layer 120. The negative terminal contact patch 415 can be coupled with the top conductive layer 120 corresponding to the top conductive layer 120. The negative terminal contact patch 415 can be coupled with the top conductive layer 120 without any soldering via wire bonding, ball bonding, compliant bonding, or direct contact, among others. The negative terminal contact patch 415 can be coupled with the top conductive layer 120 via the connector 305 attached to the top conductive layer 120. Conversely, the negative terminal of the battery block 110 can correspond to or can be coupled with the bottom conductive layer 125. The negative terminal contact patch 415 can be coupled with the top conductive layer 120 corresponding to the bottom conductive layer 125. The negative terminal contact patch 415 can be coupled with the bottom conductive layer 125 without any soldering via wire bonding, ball bonding, compliant bonding, or direct contact, among others. The negative terminal contact patch 415 can be coupled with the bottom conductive layer 125 via the connector 310 attached to the bottom conductive layer 125.

When functioning as the ground contact patch, the negative terminal contact patch 415 can be electrically coupled with at least one electrical ground of the battery cells 115 of the battery block 110. The electrical ground of the battery cells 115 can correspond to or can be defined by a bottom surface or a side wall of the battery block 110 or the battery module 105. The coupling of the negative terminal contact patch 415 with the electrical ground can be in series between the battery cells 115 and the electrical ground. The coupling of the negative terminal contact patch 415 with the electrical ground can be in parallel relative to the battery cells 115. The negative terminal contact patch 415 can be coupled with the electrical ground for the battery cells 115 of the battery block 110 without any soldering without any soldering via wire bonding, ball bonding, compliant bonding, or direct contact, among others. The negative terminal contact patch 415 can be electrically coupled with the electrical ground for the battery cells 115 of the battery block 110 via a connector separate from the connectors 305 and 310.

The sense circuit board 130 can define or have at least one sensor contact patch 420. The sensor contact patch 420 can be electrically coupled with at least one sensor to measure (e.g., detect or receive information about) one or more characteristics of components of the battery module 105. The sensor can be connected, arranged, or disposed on a component of the battery module 105 to be measured, such as the battery block 110 and the battery cells 115, among others. The sensor can include a thermometer (e.g., the thermistor 315), a pressure gauge, a force meter, and a gas detector as described above, among others. The sensor contact patch 420 can be electrically coupled with the sensor via a connector. The connector can be an electrically conductive wire to relay measurements from the sensor to the sensor contact patch 420. The sensor contact patch 420 can be coupled with the sensor without any soldering via wire bonding, ball bonding, compliant bonding, or direct contact, among others.

The sense circuit board 130 can have one or more conductive trace lines, such as a first conductive trace line 425, a second conductive trace line 430, a third conductive trace line 435, and a fourth conductive trace line 440, among others. Each conductive trace line can be an electrically conductive wire or connector embedded along, on, or within the sense circuit board 130. At least a portion of the conductive trace line can span or can be arranged or disposed along one or more surfaces of the sense circuit board 130. At least a portion of the conductive trace line can traverse within a body of the sense circuit board 130. The conductive trace lines can be etched, printed, laminated, or otherwise added to the sense circuit board 130. The conductive trace lines can be comprised of an electrically conductive material. The electrically conductive material for the conductive trace lines can include a metallic material, such as aluminum, an aluminum alloy with copper, silicon, tin, magnesium, manganese or zinc (e.g., of the aluminum 1000, 4000, or 5000 series), iron, an iron-carbon alloy (e.g., steel), silver, nickel, copper, and a copper alloy, among others. The conductive trace lines can be electrically isolated from one another by the electrically insulating material of the sense circuit board 130.

One end of each conductive trace line can be connected with one of the contact patches to electrically couple the conductive trace line with the contact patch. One end of the first conductive trace line 425 can be connected with the first positive terminal contact patch 405. The first conductive trace line 425 can be electrically coupled with the first positive terminal contact patch 405. The first conductive trace line 425 can be electrically coupled to one of the top conductive layer 120 or the bottom conductive layer 125 corresponding to the positive terminal of the battery block 110 (e.g., the battery block 110 depicted on the right) via the first positive terminal contact patch 405. One end of the second conductive trace line 430 can be connected with the second positive terminal contact patch 410. The second conductive trace line 430 can be electrically coupled with the second positive terminal contact patch 410. The second conductive trace line 430 can be electrically coupled to one of the top conductive layer 120 or the bottom conductive layer 125 corresponding to the positive terminal of the battery block 110 (e.g., the battery block 110 on the left) via the second positive terminal contact patch 410. One end of the third conductive trace line 435 can be connected with the negative terminal contact patch 415. The third conductive trace line 435 can be electrically coupled with the negative terminal contact patch 415. The third conductive trace line 435 can be electrically coupled with the negative terminal the battery block 110 (e.g., battery block 110 on right) via the negative terminal contact patch 415. One end of the fourth conductive trace line 440 can be connected with the sensor contact patch 420. The fourth conductive trace line 440 can be electrically coupled with the sensor contact patch 420. The fourth conductive trace line 440 can be electrically coupled with the sensor via the sensor contact patch 420. In this manner, an electrical signal can be relayed from the component of the battery module 105 via the conductive trace lines of the sense circuit board 130.

The sense circuit board 130 can have at least one connector 445. The connector 445 can define a port to couple with at least one component outside the sense circuit board 130 to relay at least one signal indicative of one or more characteristics of the components of the battery module 105. The connector 445 can have one or more connection elements to electrically couple the components of the sense circuit board 130 with at least one component outside the sense circuit board 130. The connection elements of the connector 445 can include a pin (e.g., as depicted), a lead, a surface mount, or a through-hole, among others. The connection elements can provide a physical connection and an electrical coupling between components of the sense circuit board 130 and the at least one component outside the sense circuit board 130. The connector elements of the connector 445 electrically coupled with at least one of the first positive terminal contact patch 405, the second positive terminal contact patch 410, and the negative terminal contact patch 415 can relay a signal indicative of the voltage and current outputted by the battery cells 115 of the battery block 110. The connector elements of the connector 445 electrically coupled with the negative terminal contact patch 415 can relay a signal indicative of voltage and current relative to the voltage and current measured from the first positive terminal contact patch 405 or the second positive terminal contact patch 410. The connector elements of the connector 445 electrically coupled with the at least one sensor contact patch 420 can relay a signal indicative of temperature, pressure, and gaseous substances emitted from the battery block 110.

At least one of the connector elements of the connector 445 can be dedicated to the first positive terminal contact patch 405. The other end of the first conductive trace line 425 can be connected to at least one of the connection elements of the connector 445. The connector 445 can be electrically coupled with the first positive terminal contact patch 405 via the first conductive trace line 425 to relay a signal from one of the top conductive layer 120 or the bottom conductive layer 125 corresponding to the positive terminal. At least one of the connector elements of the connector 445 can be dedicated to the second positive terminal contact patch 410. The other end of the second conductive trace line 430 can be connected to at least one of the connection elements of the connector 445. The connector 445 can be electrically coupled with the second positive terminal contact patch 410 via the second conductive trace line 430 to relay a signal from one of the top conductive layer 120 or the bottom conductive layer 125 corresponding to the positive terminal of the battery block 110 (e.g., the battery block 110 on the left). At least one of the connector elements of the connector 445 can be dedicated to the negative terminal contact patch 415. The other end of the third conductive trace line 435 can be connected to at least one of the connection elements of the connector 445. The connector 445 can be electrically coupled with the negative terminal contact patch 415 via the third conductive trace line 435. At least one of the connector elements of the connector 445 can be dedicated to the sensor contact patch 420. The other end of the fourth conductive trace line 440 can be connected to at least one of the connection elements of the connector 445. The connector 445 can be electrically coupled with the sensor contact patch 420 via the fourth conductive trace line 440 to relay a signal from the sensor (e.g., thermistor 315).

The sense circuit board 130 can be electrically coupled with at least one battery management unit (BMU) 460. The connector 445 of the sense circuit board 130 can be connected to the BMU 460 via a data harness 465 (sometimes referred herein as a “cable harness,” “cable assembly,” “wiring assembly,” and “wire harness”). The data harness 465 can include a set of wiring extending from the BMU 460. One end of each wiring of the data harness 465 can be electrically coupled with a component of the BMU 460 via at least one connector element (e.g., a pin, a lead, a surface mount, or a through-hole). The other end of each wiring of the data harness 465 can be electrically coupled with the connector 445. With one the end to be connected with the connector 445, the data harness 465 can one or more connector terminals to attach, join, or otherwise connect to the one or more connector elements of the connector 445. The one or more connector terminal of the data harness 465 can include a pin, a lead, a surface mount, or a through-hole, among others. The connector terminal can provide a physical connection and an electrical coupling between the wiring of the data harness 465 and the connector 445.

The connector terminal of the data harness 465 can be connected to at least one connector element of the connector 445 to electrically couple with one of the components of the sense circuit board 130. At least one connector terminal of the data harness 465 can be electrically coupled with the first positive terminal contact patch 405 and the first conductive trace line 425 via the corresponding connector element of the connector 445. At least one connector terminal of the data harness 465 can be electrically coupled with the second positive terminal contact patch 410 and the second conductive trace line 430 via the corresponding connector element of the connector 445. At least one connector terminal of the data harness 465 can be electrically coupled with the negative terminal contact patch 415 and the third conductive trace line 435 via the corresponding connector element of the connector 445. At least one connector terminal of the data harness 465 can be electrically coupled with the sensor contact patch 420 and the fourth conductive trace line 440 via the corresponding connector element of the connector 445.

Via the connection with the data harness 465, the connector 445 can relay one or more signals to the BMU 460 from the sense circuit board 130. The signal can be indicative of at least one characteristic of one or more components of the battery module 105, such as the battery block 110, the battery cells 115, and the sensors. The signal can include raw data to be processed by the BMU 460 to determine or identify the characteristics of the components of the battery module 105. The characteristics indicated by the signal can include: voltage outputted or generated by the battery cells 115, current outputted or generated by the battery cells 115, temperature of heat released or generated from the battery block 110, pressure exerted or produced from within the battery block 110, and an indication or presence of gaseous substances emitted from the battery cells 115 of the battery block 110. The characteristics can be relayed or acquired from the first positive terminal contact patch 405 via the first conductive trace line 425, the second positive terminal contact patch 410 via the second conductive trace line 430, and the negative terminal contact patch 415 via the third conductive trace line 435. The characteristics can also be relayed or acquired from the one or more sensors coupled to the sense circuit board 130 (e.g., via the sensor contact patch 420) and relayed through the conductive trace lines (e.g., fourth conductive trace line 440).

The apparatus 100 can include at least one battery management unit (BMU) 460 (sometimes herein referred to as a battery management system (BMS)). The BMU 460 can include at least one processor, at least one memory, at least one input/output (I/O) interface, and at least communication interface. The processors of the BMU 460 can be, for example, a field-programmable gate array (FPGA), a system on a chip (SOC), a microcontroller, or an application-specific integrated circuit (ASIC), or other logical circuitry, to carry out the functionalities detailed herein. The BMU 460 can include one or more components of a computing system 800 as detailed herein below. The one or more components of the BMU 460 can be positioned, distributed, arranged, or disposed in any manner relative to the battery module 105 or to the one or more battery blocks 110 of the battery module 105. The BMU 460 can be integrated one or more of the battery blocks 110 of the battery module 105. For example, the processors and memory of the BMU 460 can be distributed along a top surface or within a body of the battery block 110 between individual battery cells 115. The BMU 460 can be integrated into the battery module 105. For example, the processors and memory of the BMU 460 can be distributed along a top surface or with a body of the battery module 105 between the battery blocks 110 as well as a top surface of the battery blocks 110. The BMU 460 can be integrated into the battery module 105 and external to any of the battery blocks 110 within the battery module 105. For example, the BMU 460 can be disposed between two battery blocks 110 of the battery module 105. The BMU 460 can be physically remote from the one or more battery blocks 110 or the battery module 105. For example, the battery module 105 along with the battery blocks 110 can be located in a bottom of the electrical vehicle along a chassis. In contrast, the BMU 460 can be situated in a hood of the vehicle separated from the battery module 105 or the battery blocks 110. A subset of the components of the BMU 460 can be physically remote from the one or more battery blocks 110 or the battery module 105, while another subset of the components of the BMU 460 can be integrated into the battery block 110 or the battery module 105.

Coupled with at least one sense circuit board 130, the BMU 460 can receive the signal from the sense circuit board 130. Using the characteristics of components of the battery module 105 indicated by the signal, the BMU 460 can control various components of the battery module 105. For example, the BMU 460 can determine the voltage and current outputted from the battery cells 115 from the signals relayed from the connection with the first positive terminal contact patch 405, the second positive terminal contact patch 410, and the negative terminal contact patch 415. The BMU 460 can compare the voltage and the current with a normal operation range for voltage, current, and power for the battery cells 115 of the battery module 105. Based on the comparison, the BMU 460 can adjust the voltage or current drawn from the battery cells 115 of the battery module 105. The BMU 460 can also identify a temperature from heat released from the battery block 110 using the signal relayed from the sensor contact patch 420 coupled to the thermometer (e.g., thermistor 315). The BMU 460 can compare the temperature to a normal operation threshold (e.g., 150° C.). The BMU 460 can determine that the identified temperature for the battery block 110 is greater than the normal operation threshold. Responsive to the determination, the BMU 460 can increase an amount of coolant to provide to a cold plate thermally coupled with the battery block 110 to cool the battery block 110. The BMU 460 can also determine a pressured released from within the battery block 110 using the signal relayed from the sensor contact patch 420 coupled to a force meter or pressure gauge. The BMU 460 can compare the pressure to a normal operation threshold. The BMU 460 can determine that the pressure for the battery block 110 is greater than the normal operation threshold. Responsive to the determination, the BMU 460 can increase an amount of coolant to provide to a cold plate thermally coupled with the battery block 110 to cool the battery block 110 to reduce the pressure. In addition, the BMU 460 can determine a presence of gaseous substances based on the signal relayed from the sensor contact patch 420 connected to a gas detector. Responsive to the determination, the BMU 460 can disconnect (or cause an open circuit) the battery cells 115 of the battery block 110 from powering other components.

The sense circuit board 130 can define or have one or more mounting space 450 to integrate or incorporate the sense circuit board 130 to the battery module 105. Each mounting space 450 can define an area through the sense circuit board 130 to insert a mounting element to attach, hold, fasten, or otherwise join the sense circuit board 130 to the battery module 105. The area can span one side of the sense circuit board 130 to the opposite side of the sense circuit board 130. The mounting space 450 can be aligned or collinear with a corresponding area of the battery module 105 to secure the mounting element. The area of the battery module 105 can define a hole, aperture or opening to secure the mounting element through the mounting space 450 to integrate the sense circuit board 130 onto the battery module 105. The mounting element (sometimes referred herein as a fastening element) can include, for example, as a screw, a bolt, a clasp, a bucket, a tie, or a clip, among others. By insertion into the mounting space 450, the mounting element can firmly hold or secure the sense circuit board 130 onto a surface of the battery module 105, such as the top surface 205. The mounting element can firmly hold or secure the sense circuit board 130 across multiple component of the battery module 105, such as a surface of the joint structure 200 or a surface of one or more battery blocks 110. For example, one mounting space 450 can fit over an area of a top surface of one battery block 110, while another mounting space 450 can fit over another area of a top surface of another battery block 110. The mounting spaces 450 can be of any shape, such as a triangle, a square, a rectangular, a pentagon, or a hexagon, among others. The shape of the mounting spaces 450 can also be circular (e.g., as illustrated), ovular, or elliptical, among others. The length of the mounting space 450 can range between 1.5 mm to 4.5 mm. The width or diameter of the mounting space 450 can range between 1.5 mm to 4.5 mm. The shapes and the dimensions can vary among the mounting spaces 450 of the sense circuit board 130. The battery module 105 can also define a space along a portion of a surface of one or more components (E.g., joint structure 200 or battery blocks 110) to hold or secure the sense circuit board 130. At least a portion of the sense circuit board 130 can be held or secured to the surface of the battery module 105 using insert molding, sealing, an adhesive. The portion of the sense circuit board 130 can include, for example, an area about each corner, a length, or a width of the sense circuit board 130.

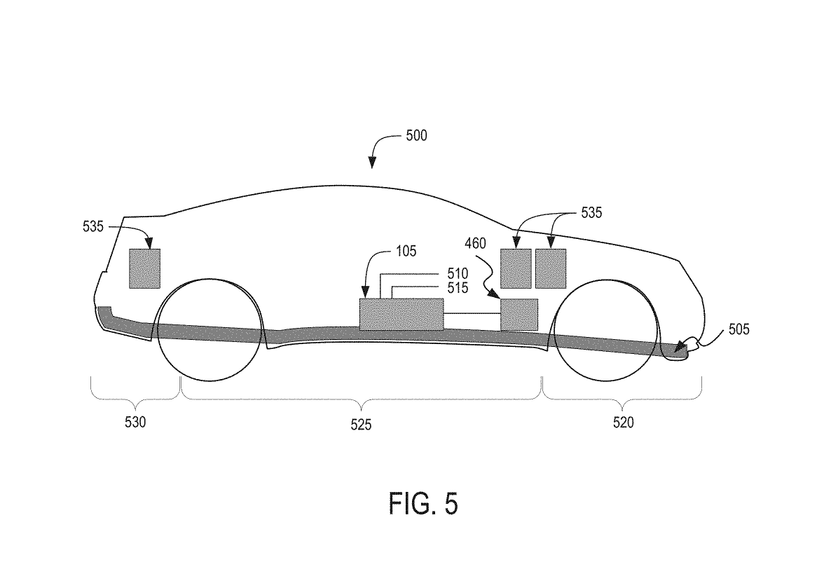

FIG. 5, among others, depicts a cross-section view of an electric vehicle 500 installed with a battery module 105. The electric vehicle 500 can include a chassis 505 (e.g., a frame, internal frame, or support structure). The chassis 505 can support various components of the electric vehicle 500. The chassis 505 can span a front portion 520 (e.g., a hood or bonnet portion), a body portion 525, and a rear portion 530 (e.g., a trunk portion) of the electric vehicle 500. The battery module 105 and the BMU 460, and can be installed or placed within the electric vehicle 500. The one or more battery module 105 can be installed on the chassis 505 of the electric vehicle 500 within the front portion 520, the body portion 525 (as depicted in FIG. 5), or the rear portion 530. The battery module 105 can provide electrical power to one or more other components 535 by electrically coupling with at least one positive current collector 510 (e.g., a positive busbar) and at least one negative current collector 515 (e.g., a negative busbar). The positive current collector 510 can be electrically coupled with the positive terminal of the battery module 105. The negative current collector 515 can be electrically coupled with the negative terminal of the battery module 105. For example, if the top conductive layer 120 of the battery blocks 110 defines the positive terminal and the bottom conductive layer 125 of the battery pack defines the negative terminal, the positive current collector 510 can be electrically coupled with the top conductive layer 120 and the negative current collector 515 can be electrically coupled with the bottom conductive layer 125. The one or more components 535 can include an electric engine, an entertainment system (e.g., a radio, display screen, and sound system), on-board diagnostics system, and electric control units (ECUs) (e.g., an engine control module, a transmission control module, a brake control module, and a body control module), among others.

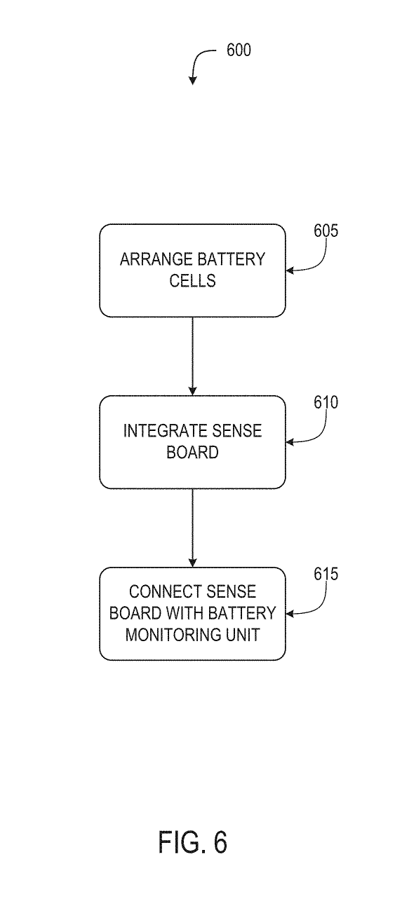

FIG. 6, among others, depicts a flow diagram of a method 600 of providing energy storage with component monitoring capacity. The method 600 can be implemented using any of the components detailed herein in conjunction with FIGS. 1-5 and 8. The method 600 can include arranging battery cells 115 (ACT 605). The battery cells 115 can store and provide electrical energy (e.g., to components in the electric vehicle 500). Each battery cell 115 can have a positive terminal and a negative terminal. Each terminal can be accessed or exposed to one surface of the battery cell 115 (e.g., a top surface). The battery cells 115 can be inserted or added to battery blocks 110. Each battery block 110 can define a set of holders to secure or contain the battery cells 115. Each battery block 110 can also have a top conductive layer 120 and a bottom conductive layer 125. The top conductive layer 120 can be electrically coupled with one polarity terminal of the battery cells 115, while the bottom conductive layer 125 can be electrically coupled with the other polarity terminal of the battery cells 115. A set of battery blocks 110 can be attached to one another via a joint structure 200 to form a battery module 105. The joint structure 200 can be defined along the side walls of multiple battery blocks 110. A set of battery modules 105 can be attached to one another to form a battery pack.

The method 600 can include integrating a sense circuit board 130 (ACT 610). The sense circuit board 130 can include one or more contact patches. A set of contact patches, such the first positive terminal contact patch 405, the second positive terminal contact patch 410, and the negative terminal contact patch 415 can be used to relay voltage and current outputted from the battery cells 115 of the battery module 105. The first positive terminal contact patch 405 can be connected to one of the top conductive layer 120 or the bottom conductive layer 125 corresponding to the positive terminal to electrically couple with the positive terminals of the battery cells 115 of the battery block 110 (e.g., the battery block 110 depicted on the right). The second positive terminal contact patch 410 can be connected to one of the top conductive layer 120 or the bottom conductive layer 125 corresponding to the positive terminal to electrically couple with the positive terminals of the battery cells 115 of the other battery block 110 (e.g., the battery block 110 depicted on the left). The negative terminal contact patch 415 can be connected to the negative terminal of the same battery block 110 connected to the first positive terminal contact patch 405. The sense circuit board 130 can include a sensor contact patch 420 connected to a sensor to measure one or more characteristics of the components of the battery module 105. The one or more characteristics measured by the sensor can include a temperature, a pressure, and presence of gaseous substances. The sense circuit board 130 can include a set of conductive trace line to electrically couple the contact patches with a connector 445 to relay one or more signals to a component outside the sense circuit board 130. The sense circuit board 130 can be integrated within, on, or in multiple components of the battery module 105, such as along the top surface 205 of the battery module 105, top surfaces of multiple battery blocks 110, or the joint structure 200.

The method 600 can include connecting the sense circuit board 130 with a battery monitoring unit (BMU) 460 (ACT 615). The sense circuit board 130 can be coupled with the BMU 460 via a data harness 465. The data harness 465 can include a set of wires extending from the BMU 460. The data harness 465 can include one or more port terminals to connect with connector elements of the connector 445. The port terminal and connector elements can be a pin, a lead, a surface mount, or a through-hold to connect with each other to establish an electrical coupling between the BMU 460 and the contact patches of the sense circuit board 130. Once connected, the connector 445 of the sense circuit board 130 can relay one or more signals indicative of various characteristics of the components of the battery module 105 to the BMU 460. The characteristics can include voltage and current drawn from the battery cells 115 of the battery block 110, the temperature from heat released from the battery block 110, the pressure exerted from within the battery block 110, and detection of gaseous substances emitted from the battery block 110. Using the measured characteristics, the BMU 460 can change or set operations of the various components of the battery module 105.

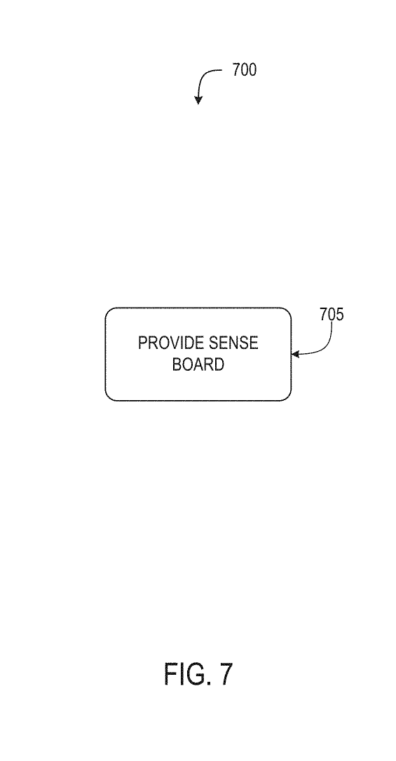

FIG. 7, among others, depicts a flow diagram of a method 700 of providing energy storage with component monitoring capacity. The method 700 can be implemented using any of the components detailed herein in conjunction with FIGS. 1-5 and 8. The method 700 can include providing a sense circuit board 130 (ACT 705). The sense circuit board 130 can be integrated onto a battery module 105 installed in an electric vehicle 500. The sense circuit board 130 can be disposed between multiple battery blocks 110 of the battery module 105 along the top surface 205 of the battery module 105 or the joint structure 200 between battery blocks 110. The sense circuit board 130 can be jointed onto the battery module 105 at the one or more mounting spaces 450 defined along the sense circuit board 130. The sense circuit board 130 can have a first positive terminal contact patch 405 electrically coupled with a positive terminal defined by the battery module 105. The positive terminal can correspond to one of the top conductive layer 120 or the bottom conductive layer 125 of one of the battery blocks 110. The sense circuit board 130 can have a second positive terminal contact patch 410 electrically coupled with a positive terminal defined by the other battery block 110. The positive terminal can correspond to one of the top conductive layer 120 or the bottom conductive layer 125 of one of the other battery blocks 110 in the battery module 105. The sense circuit board 130 can have a negative terminal contact patch 415 electrically coupled with the negative terminal of one of the battery blocks 110. The sense circuit board 130 can have a sensor contact patch 420 coupled with a sensor (e.g., thermistor) disposed or arranged in the battery module 105. The sensor can measure various characteristics of the components of the battery module 105.

The contact patches can be electrically coupled with a connector 445 via one or more conductive trace line. A first conductive trace line 425 can electrically couple the first positive terminal contact patch 405 with the connector 445. A second conductive trace line 430 can electrically couple the second positive terminal contact patch 410 with the connector 445. A third conductive trace line 435 can electrically couple the negative terminal contact patch 415 with the connector 445. A fourth conductive trace line 440 can electrically couple the sensor contact patch 420 with the connector 445. Through the coupling with the connector 445, the first positive terminal contact patch 405, the second positive terminal contact patch 410, the negative terminal contact patch 415, and the sensor contact patch 420 can be electrically coupled with a battery management unit (BMU) 460 using a data harness 465. A signal indicative of the characteristics of the components of the battery module 105 can be relayed through the contact patches, the conductive trace lines, and the connector 445 to the BMU 460.

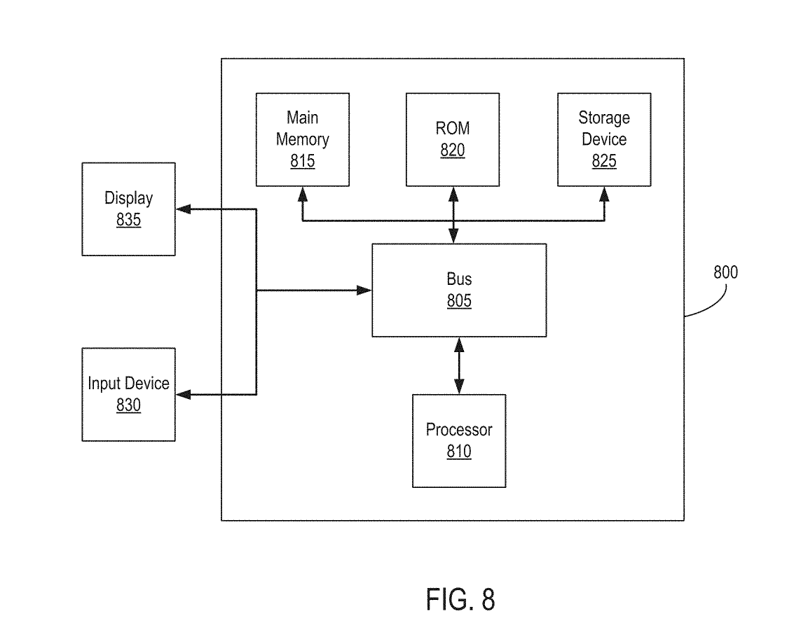

FIG. 8 depicts a block diagram of an example computer system 800. The computer system or computing device 800 can include or be used to implement the BMU 460 for instance. The computing system 800 includes at least one bus 805 or other communication component for communicating information and at least one processor 810 or processing circuit coupled to the bus 805 for processing information. The computing system 800 can also include one or more processors 810 or processing circuits coupled to the bus for processing information. The computing system 800 also includes at least one main memory 815, such as a random access memory (RAM) or other dynamic storage device, coupled to the bus 805 for storing information, and instructions to be executed by the processor 810. The main memory 815 can be or include the BMU 460. The main memory 815 can also be used for storing position information, vehicle information, command instructions, vehicle status information, environmental information within or external to the vehicle, road status or road condition information, or other information during execution of instructions by the processor 810. The computing system 800 may further include at least one read only memory (ROM) 820 or other static storage device coupled to the bus 805 for storing static information and instructions for the processor 810. A storage device 825, such as a solid state device, magnetic disk or optical disk, can be coupled to the bus 805 to persistently store information and instructions. The storage device 825 can include or be part of the BMU 460.

The computing system 800 may be coupled via the bus 805 to a display 835, such as a liquid crystal display, or active matrix display, for displaying information to a user such as a driver of the electric vehicle 500. An input device 830, such as a keyboard or voice interface may be coupled to the bus 805 for communicating information and commands to the processor 810. The input device 830 can include a touch screen display 835. The input device 830 can also include a cursor control, such as a mouse, a trackball, or cursor direction keys, for communicating direction information and command selections to the processor 810 and for controlling cursor movement on the display 835. The display 835 can be coupled with the BMU 460 to display various diagnostic data regarding the apparatus 100.

The processes, systems and methods described herein can be implemented by the computing system 800 in response to the processor 810 executing an arrangement of instructions contained in main memory 815. Such instructions can be read into main memory 815 from another computer-readable medium, such as the storage device 825. Execution of the arrangement of instructions contained in main memory 815 causes the computing system 800 to perform the illustrative processes described herein. One or more processors in a multi-processing arrangement may also be employed to execute the instructions contained in main memory 815. Hard-wired circuitry can be used in place of or in combination with software instructions together with the systems and methods described herein. Systems and methods described herein are not limited to any specific combination of hardware circuitry and software.

Although an example computing system has been described in FIG. 8, the subject matter including the operations described in this specification can be implemented in other types of digital electronic circuitry, or in computer software, firmware, or hardware, including the structures disclosed in this specification and their structural equivalents, or in combinations of one or more of them.

While operations may be depicted in the drawings or described in a particular order, such operations are not required to be performed in the particular order shown or described, or in sequential order, and all depicted or described operations are not required to be performed. Actions described herein can be performed in different orders.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. Further, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. For example, rather than or in addition to the sense circuit board 130, conductive traces can be etched directly into components of the battery module 105 such as battery current collectors to provide voltage information to the BMU. Further, rather than a dedicated BMU board, BMU electronics can reside on an isolated laminated layer (e.g., a laminated, conformal coated layer) atop of the current collectors. In this example dedicated printed circuit boards for the sense circuit board 130 or for the BMU can be avoided. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

What is claimed is:

1. An apparatus to store electrical energy in an electric vehicle to power the electric vehicle, comprising:
a battery block disposed in a battery pack of the electric vehicle to power the electric vehicle;
a plurality of battery cells disposed within the battery block to store electrical energy;
an integrated current collector to electrically couple the plurality of battery cells in parallel, the integrated current collector having a first conductive layer to connect with first polarity terminals of the plurality of battery cells and a second conductive layer to connect with second polarity terminals of the plurality of battery cells, the second conductive layer electrically isolated from the first conductive layer; and
a circuit board to couple with a battery monitoring unit (BMU), the circuit board at least partially incorporated into the battery block and having:
a first contact patch to electrically couple with the first conductive layer,
a second contact patch to electrically couple with the second conductive layer,
a third contact patch to connect to a thermistor to measure a temperature of the battery block,
a plurality of conductive traces embedded along the circuit board, and
a connector to electrically couple the first contact patch, the second contact patch, and the third contact patch via the plurality of conductive traces to the BMU to relay a signal indicative of a characteristic of a component of the battery block.

2. The apparatus of claim 1, comprising:
a second battery block disposed in the battery pack;
a second plurality of battery cells disposed in the second battery block; and
the circuit board integrated at least partially into the battery module between the battery block and the second battery block.

3. The apparatus of claim 1, comprising:
the thermistor disposed between a side wall of the battery block and a side of a second battery block of the battery module to measure the temperature of the battery block, the battery block having a first subset of battery of the plurality of battery cells, the second battery block having a second subset of battery cells of the plurality of battery cells.

4. The apparatus of claim 1, comprising:
the connector of the circuit board having a port to couple with a data harness of the BMU to relay signals indicative of characteristics of the component of the battery block, the data harness having a first terminal, a second terminal, and a third terminal, the port of the connector having:
a first connector element to electrically couple the first contact patch with the first terminal of the data harness to relay information regarding at least one of a voltage and a current of the battery block;
a second connector element to electrically couple the second contact patch with the second terminal of the data harness to relay information regarding at least one of the voltage and the current of the battery block; and
a third connector element to electrically couple the third contact patch with the third terminal of the data harness to relay information regarding the temperature measured by the thermistor.

5. The apparatus of claim 1, comprising:
the first contact patch of the circuit board coupled with the first conductive layer via at least one of direct contact or wire bonding; and
the second contact path of the circuit board coupled with the second conductive layer via at least one of direct contact or wire bonding.

6. The apparatus of claim 1, comprising:
the connector of the circuit board to electrically couple the first contact patch, the second contact patch, and the third contact patch via the plurality of conductive traces to the BMU external to the battery block via a data harness.

7. The apparatus of claim 1, comprising:
the connector of the circuit board to electrically couple the first contact patch, the second contact patch, and the third contact patch via the plurality of conductive traces to the BMU having at least one component incorporated into a layer electrically isolated to at least one of the first conductive layer and the second conductive layer.

8. The apparatus of claim 1, comprising:
the circuit board having:
a fourth contact patch to electrically couple with a sensor to measure a second characteristic of the battery block, the sensor disposed in the battery block; and
the connector to electrically couple the fourth contact patch via at least one of the plurality of conductive traces to the BMU to relay the signal indicative of the second characteristic.

9. The apparatus of claim 1, comprising:
the circuit board having:
a fourth contact patch to electrically couple with a positive terminal of the plurality of battery cells disposed in a second battery block of the battery module; and
the connector to electrically couple the fourth contact patch via at least one of the plurality of conductive traces to the BMU to relay the signal indicative of the characteristic of the component of the second battery block relative to measurements of at least one of the first contact patch and the second contact patch.

10. The apparatus of claim 1, comprising:
the circuit board at least partially integrated along a surface of the battery block, the surface coplanar with at least one of: the first conductive layer connected with the first polarity terminals and with the second conductive layer connected with the second polarity terminals.

11. The apparatus of claim 1, comprising:
the circuit board defining a mounting space to at least partially integrate the circuit board with the battery block.

12. The apparatus of claim 1, comprising:
the circuit board having an insulating layer to cover the plurality of embedded conductive trace lines defined along a surface of the circuit board, and to expose the first contact patch, the second contact patch, and the third contact patch.

13. A circuit board to measure characteristics of battery cells for powering electric vehicles, comprising:
a first contact patch to electrically couple with a first conductive layer of an integrated current collector of a battery block to connect with first polarity terminals of a plurality of battery cells of the battery block;
a second contact patch to electrically couple with a second conductive layer of the integrated current collector of the battery block to connect with second polarity terminals of the plurality of battery cells of the battery block, the second conductive layer electrically isolated from the first conductive layer;
a third contact patch to connect to a thermistor to measure a temperature of the battery block,
a plurality of embedded conductive traces, and
a connector to electrically couple the first contact patch, the second contact patch, and the third contact patch via the plurality of embedded conductive traces to a battery monitoring unit (BMU) to relay a signal indicative of a characteristic of a component of the battery block.

14. The circuit board of claim 13, comprising:
the first contact patch of the circuit board coupled with the first conductive layer via at least one of direct contact or wire bonding; and
the second contact path of the circuit board coupled with the second conductive layer via at least one of direct contact or wire bonding.

15. The circuit board of claim 13, comprising:
a fourth contact patch to electrically couple with a sensor to measure a second characteristic of the battery block, the sensor disposed in the battery block; and
the connector to electrically couple the fourth contact patch via at least one of the plurality of conductive traces to the BMU to relay the signal indicative of the second characteristic.

16. The circuit board of claim 13, comprising:
a fourth contact patch to electrically couple with a ground positive terminal of the plurality of battery cells disposed in a second battery block of the battery module; and the connector to electrically couple the fourth contact patch via at least one of the plurality of conductive traces to the BMU to relay the signal indicative of the characteristic of the component of the second battery block relative to measurements of at least one of the first contact patch and the second contact patch.

17. The circuit board of claim 13, comprising:
the connector defining a port to couple with a data harness of the BMU to relay signals indicative of characteristics of the component of the battery block, the data harness having a first terminal, a second terminal, and a third terminal, the port of the connector having:
a first connector element to electrically couple the first contact patch with the first terminal of the data harness to relay at least one of a voltage and a current of the battery block;
a second connector element to electrically couple the second contact patch with the second terminal of the data harness to relay at least one of the voltage and the current of the battery block; and
a third connector element to electrically couple the third contact patch with the third terminal of the data harness to relay the temperature measured by the thermistor.

18. A method, comprising:
providing a circuit board to at least partially incorporate into a battery block, the circuit board having:
a first contact patch to electrically couple with a first conductive layer of an integrated current collector of the battery block to connect with first polarity terminals of a plurality of battery cells of the battery block;
a second contact patch to electrically couple with a second conductive layer of the integrated current collector of the battery block to connect with second polarity terminals of the plurality of battery cells of the battery block, the second conductive layer electrically isolated from the first conductive layer;
a third contact patch to connect to a thermistor to measure a temperature of the battery block,
a plurality of conductive traces embedded into the circuit board; and
a connector to electrically couple the first contact patch, the second contact patch, and the third contact patch via the plurality of conductive traces to a battery monitoring unit (BMU) to relay a signal indicative of a characteristic of a component of the battery block.

19. The method of claim 18, comprising:
providing the circuit board, the circuit board having:
the first contact patch of the circuit board coupled with the first conductive layer via at least one of direct contact or wire bonding; and
the second contact path of the circuit board coupled with the second conductive layer via at least one of direct contact or wire bonding.

20. The method of claim 18, comprising:
providing the circuit board, the circuit board having:
a fourth contact patch to electrically couple with a sensor to measure a second characteristic of the battery block, the sensor disposed in the battery block; and
the connector to electrically couple the fourth contact patch via at least one of the plurality of conductive traces to the BMU to relay the signal indicative of the second characteristic.
